(19) United States
(12) Patent Application Publication
(10) Pub. No.: US 2007/0131956 A1
(43) Pub. Date: Jun. 14, 2007

(54) Reflection efficiency improved light emitting element

(76) Inventor: San Bao Lin, Jhongli City (TW)

Correspondence Address: ROSENBERG, KLEIN & LEE, 3458 ELLICOTT CENTER DRIVE-SUITE 101, ELLICOTT CITY, MD, 21043, US

(21) Appl. No.: 11/503,063

(22) Filed: Aug. 14, 2006

(30) Foreign Application Priority Data
Dec. 12, 2005 (TW) 094143848

(51) Int. Cl. H01L 33/00

(52) U.S. Cl. 257/98; 257/E33.068

(57) ABSTRACT

A reflection efficiency improved light emitting element comprises a first electrode and a second electrode respectively provided on the partial surface of the first material layer and the second material layer of a light emitting diode; a light transparent electrical conductive layer provided on the partial surface of the second material layer without the second electrode; a light transparent isolation layer and a reflection layer provided on the light transparent electrical conductive layer in order; wherein, according to the light transparent electrical conductive layer and the reflection layer provided independently, the conductive evenness between the first electrode and the second electrode and the reflection efficiency of the reflection layer can be improved, and achieve the purpose of improving the brightness of the light emitting element.

### FIELD OF THE INVENTION

The present invention relates to a light emitting element, and more particularly to a reflection efficiency improved light emitting element, according to the light transparent electrical conductive layer and the reflection layer provided independently, the purpose of improving the brightness of the light emitting element being achieved.

### BACKGROUND OF THE INVENTION

A Light emitting diode (LED) comprises advantages of long lifetime, small volume, low power consumption, high speed response time, non-heat radiation, and single color light emitting; therefore, such is applied in the fields of indication light, billboard, traffic lights, vehicle lamp, display panel, communication tool, consuming electrical production, and so on.

Referring to FIG. 1, is a cross sectional view of a prior art light emitting element structure. The light emitting diode (LED) 13 comprises a first material layer 131 and a second material layer 133 stacked each other; a first electrode 171 and a second electrode 173 respectively provided on the partial surface of the first material layer 131 and the second material layer 133; wherein, the first material layer 131 and the second material layer 133 are respectively as a N type semiconductor material and a P type semiconductor, and a PN junction spontaneously formed between the first material layer 131 and the second material layer 133. When a potential difference between the first electrode 171 and the second electrode 173 is occurred, the LED 13 will generate a color light source.

Further, Due to the brightness of the LED 13 improvement, the surface of the LED 13 has provided a reflection layer 15 for directing the light source from the LED 13, for example, the surface of the second material layer 133 has provided a reflection layer 15, the forward light source L1 generated from the LED 13 can pass through the first material layer 131 to the external of the LED 13 directly, and the backward light source L2 can be reflected by the reflection layer 15 and directed to the external of the LED 13 for improving the brightness of the LED 13.

However, when the LED 13 is under high temperature environment, such as, when the LED 13 is fabricated or applied, the heat will be generated, therefore, the structure of the reflection layer 15 will be broken, and further, the reflection efficiency of the reflection layer 15 will be affected. Thus, the brightness of the LED 13 cannot be increased.

### SUMMARY OF THE INVENTION

Accordingly, how to design a novel light emitting element with improving light emitting efficiency and advantaging further manufacturing procedures, is the key point of the present invention. Therefore,

It is a primary object of the present invention to provide a reflection efficiency improved light emitting element, which can overcome the shortcomings of the above mentioned prior art light emitting element.

It is a secondary object of the present invention to provide a reflection efficiency improved light emitting element, which provides independent mechanisms respectively for the power supply and heat conduction with the power supply and reflection, such that can perform most functions from each mechanism, and achieve the purpose of improving the brightness of the light emitting element.

It is another object of the present invention to provide a reflection efficiency improved light emitting element, wherein the reflection layer and the second material layer are not contacted directly, such that can prevent the interaction from the reflection layer and the second material layer for maintaining the structure completion of reflection layer.

It is another object of the present invention to provide a reflection efficiency improved light emitting element, wherein the reflection layer and the light transparent electrical conductive layer of the second material layer are not contacted directly, which has a light transparent isolation layer for isolating each of both for preventing the interaction from the reflection layer and the light transparent electrical conductive layer to maintain the structure completion of the reflection layer.

It is another object of the present invention to provide a reflection efficiency improved light emitting element, wherein the reflection efficiency of the reflection layer will not be affected by the temperature increase, and improve the brightness of the light emitting element, when the light emitting diode is applying.

It is another object of the present invention to provide a reflection efficiency improved light emitting element, wherein the light emitting element has larger heat conductive area for reducing the probability of the heat resistance increase as the lighting period, and thus, the power consumption as the lighting period will be reduced.

It is another object of the present invention to provide a reflection efficiency improved light emitting element, wherein the light emitting element has larger heat conductive area for increasing the input power of the light emitting element, such that can reduce the cost of manufacturing.

To achieve the previous mentioned objects, the present invention provides a reflection efficiency improved light emitting element, comprising a light emitting diode, comprising a first material layer and a second material layer stacked each other, at least one first electrode provided on the partial surface of the first material layer, at least one second material layer provided on the partial surface of the second material layer; a light transparent electrical conductive layer provided on the surface of the second material layer, and electrically connected with the second electrode; a light transparent isolation layer provided on the light transparent electrical conductive layer; and a reflection layer provided on the light transparent isolation layer.

### BRIEF DESCRIPTION OF THE DRAWINGS

It will be understood that the figures are not to scale since the individual layers are too thin and the thickness differences of various layers too great to permit depiction to scale.

FIG. 1 is a structure cross sectional view of a prior art light emitting element;

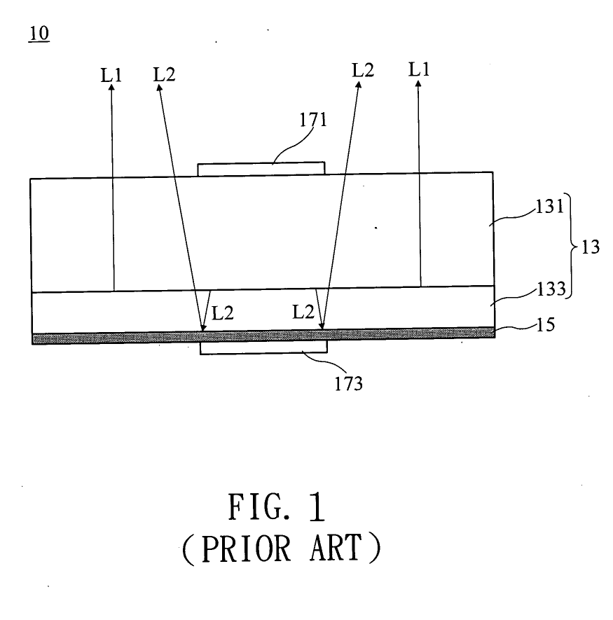

FIG. 2 is a structure cross sectional view of a preferred embodiment of the present invention reflection efficiency improved light emitting element;

FIG. 3 is a structure cross sectional view of another preferred embodiment of the present invention;

FIG. 4 is a structure cross sectional view of another preferred embodiment of the present invention;

FIG. 5 is a structure cross sectional view of another preferred embodiment of the present invention;

FIG. 6 is a structure cross sectional view of another preferred embodiment of the present invention;

FIG. 7 is a vertical view of another preferred embodiment of the present invention;

FIG. 8 is a structure cross sectional view of the above mentioned preferred embodiment of the present invention; and

FIG. 9 is a structure cross sectional view of the above mentioned preferred embodiment of the present invention.

### DETAILED DESCRIPTION OF THE INVENTION

The structural features and the effects to be achieved may further be understood and appreciated by reference to the presently preferred embodiments together with the detailed description.

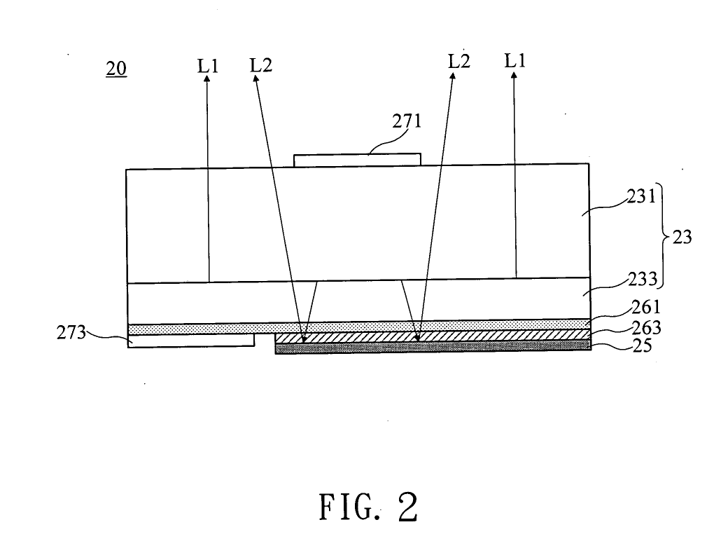

Referring to FIG. 2, is a structure cross sectional view of a preferred embodiment of the present invention reflection efficiency improved light emitting element. The light emitting element 20 comprises a light emitting diode 23, which has a first material layer 231 and a second material layer 233 stacked each other, wherein the first material layer 231 and the second material layer 233 are respectively as a N type semiconductor and a P type semiconductor material. A PN junction is formed spontaneously between the first material layer 231 and the second material layer 233. The surface of the first material layer 231 of the light emitting diode 23 comprises at least one first electrode 271; the surface of the second material layer 233 comprises a light transparent electrical conductive layer 261 and at least one second electrode 273, wherein the second electrode 273 and the light transparent electrical conductive layer 261 are electrically connected. And, the light transparent electrical conductive layer 261 can be extended to the place between the second electrode 273 and the second material layer 233, a light transparent isolation layer 263 and a reflection layer 25 are provided on the light transparent electrical conductive layer 261 in order.

When a potential difference occurs between the first electrode 271 and the second electrode 273, the light emitting diode 23 will generate a color source, wherein the second electrode 273 will supply power for the second material layer 233 of the light emitting diode 23 through the light transparent electrical conductive layer 261. The power source signal supplied from the second electrode 273 will evenly spread around the second material layer 233 for generating an evener color source and a larger lighting area from the light emitting diode 23.

The color source generated from the light emitting diode 23, comprises a forward light source L1 and a backward light source L2, wherein the forward light source L1 is generated from PN junction, and passed through the first material layer 231 to the external of the light emitting element 20; the backward light source L2 is generated from the PN junction, and reflected to the external of the light emitting element 20 by the reflection layer 25. Therefore, the reflection layer 25 is provided for directing most of backward light source L2 out of the light emitting element 20, and mixing with the forward light source L1 for achieve the purpose of increasing the brightness of the light emitting element 20.

The directing index of the backward light source L1 and the reflection efficiency of the reflection layer 25 are as proportion relationship. The present invention mainly comprises the light transparent isolation layer 263 to isolate the power source signal generated from the second electrode 273, and the power source signal will not be transmitted to the reflection layer 25, thus, the reflection efficiency of the reflection layer 25 can be maintained. And, the light transparent electrical conductive layer 263 is provided between the second material layer 233 and the reflection layer 25 for preventing the material mix of the second material layer 233 and the reflection layer 25 to achieve the purpose of maintaining the structure completion of the reflection layer 25. According to the reflection layer 25, the light transparent isolation layer 263, and the light transparent electrical conductive layer 261 independently provided, the application function and purpose of each element can be distinguished, thus, the purpose can be achieved by separating the reflection and power supply of the light emitting element 20.

The light transparent electrical conductive layer 261 is made by a material with the feather of light transparent electrical conduction, such as a metal oxide (light transparent electrical conductive film; ITO or IZO) or a metal thin-film (as NiAu), and the light transparent isolation layer 263 is an isolation material, for example TIO2, SiO2, Al2O3, Si3N4 or a combination thereof. The reflection layer 25 can be as a metal material with the feather of reflection, such as an aluminum, a silver, and so on. Of course, according to another preferred embodiment of the present invention, the reflection layer 25 can be as a multilayer thin-films reflection mirror with high reflection index, such as the materials of TiO2, SiO2, or Al2O3, which can advantage the increase of the reflection efficiency of the reflection layer 25.

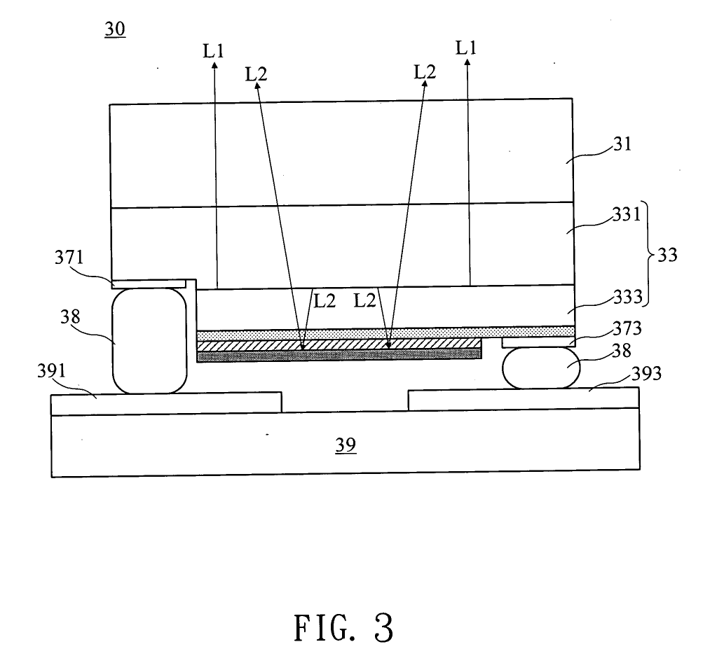

Referring to FIG. 3, is a structure cross sectional view of another preferred embodiment of the present invention. The light emitting element 30 comprises a light emitting diode 33, a light transparent substrate 31 provided on another side of a first material layer 331 of the light emitting diode 33, wherein the refraction index of the light transparent substrate 31 is larger than 1.7. The light emitting diode is provided on a power supply substrate 39 by a flip chip way. The first electrode 371 and the second electrode 373 can be electrically connected with a first power supply circuit 391 and a second power supply circuit 393 of the power supply substrate 39 by applying an electrical conductive adhesive layer 38, such as a solder ball, a gold to gold interconnect material, or a intermetallic material (AuSn,AgSn,AuGe . . . ), thus, the purpose of power supplying to the first material layer 331 and the second material layer 333 can be achieved.

The material of the light emitting diode 33 can be selectively as a nitride compound, a quaternary compound, or a ternary compound, and the light transparent substrate 31 can be selectively as a material with well light transmittance, such as one of a sapphire, a silicon carbide, a gallium phosphide, a gallium arsenide phosphide, a zinc selenide, a zinc sulfide, a zinc sulfide selenide, and a combination thereof.

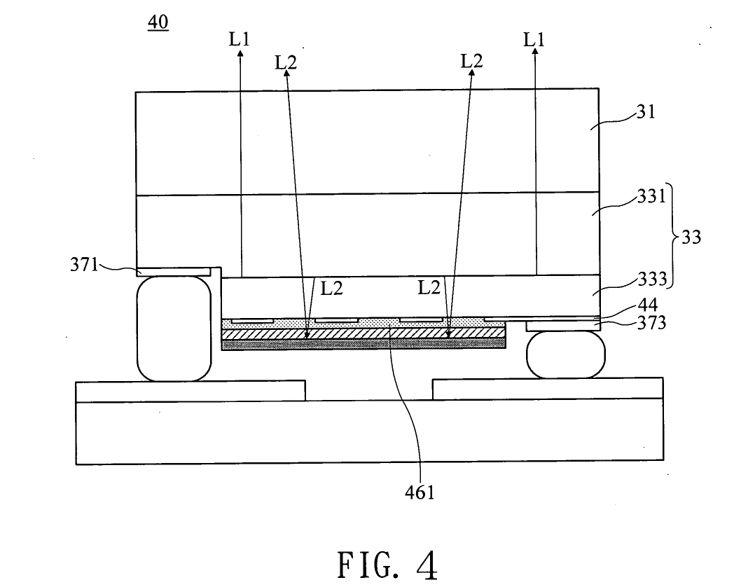

Referring to FIG. 4, is a structure cross sectional view of another preferred embodiment of the present invention. The light emitting element 40 comprises a light emitting diode 33 provided on a light transparent substrate 31, wherein the light emitting diode 33 comprises a first material layer 331 and a second material layer 333 stacked each other. A first electrode 371 is provided on the partial surface of the first material layer 331, a second material layer 373 and a light transparent electrical conductive layer 461 are provided on the partial surface of the second material layer 333, and the second electrode 373 and the light transparent electrical conductive layer 461 are electrically connected.

A plurality of ohm contact points 44 is provided between the light transparent electrical conductive layer 461 and the second material layer 333 for reducing the impedance between the light transparent electrical conductive layer 461 and the second material layer 333. And, due to the provided of the ohm contact points, the second electrode 373 and the light transparent electrical conductive layer 461 are electrically connected.

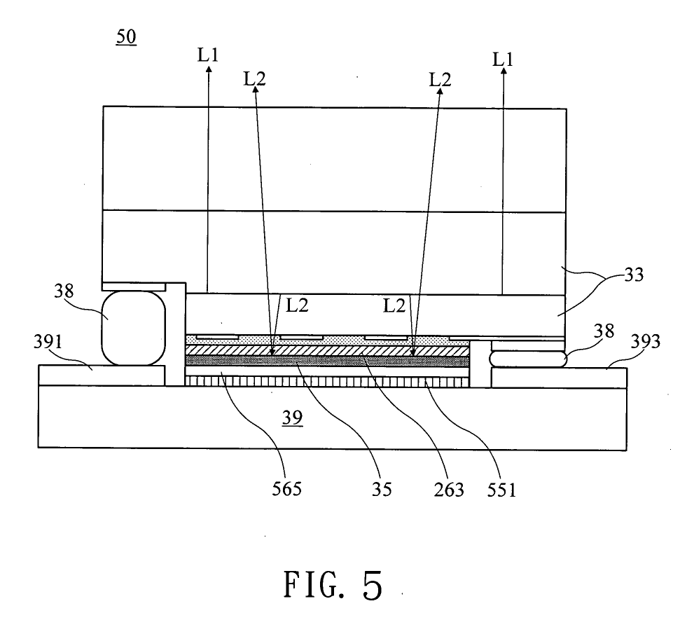

Referring to FIG. 5, is a structure cross sectional view of another preferred embodiment of the present invention. The light emitting element 50 comprises a light emitting diode 33 provided on a power supply substrate 39, wherein a first power supply circuit 391 and a second power supply circuit 393 of the power supply substrate 39 are electrically connected with the light emitting diode 33. And, at least one heat conductive layer 551 is provided on the bottom surface of the reflection layer 35 within the light emitting diode 33, wherein the heat conductive layer 551 can be made by a material with high heat conductivity. Thus, the heat generated from the light emitting diode 33 can be easily sunk.

According to the provided of the light transparent isolation layer 263, the path of the power supply and the heat conductive layer 551 can be distinguished, thus, the purpose of separating the heat and electricity within the light emitting element can be achieved. Further, a isolation layer 565 is provided between the reflection layer 35 and the heat conductive layer 551 for preventing the interaction of the heat conductive layer 551 and the reflection layer 35, while the heat conductive layer 551 is to be provided. Therefore, the purpose of maintaining the reflection efficiency of the reflection layer 35 can be achieved.

According to another preferred embodiment of the present invention, the heat conductive layer 551 and the electrical conductive adhesive layer 38 are made by the same material. And, when the electrical conductive adhesive layer 38 is to be provided within the light emitting diode 33, the heat conductive layer 551 is formed simultaneously. In other words, the heat conductive layer 551 is connected with the reflection layer 35 and the power supply substrate 39 of the light emitting diode 33, that is, such can advantage the provided of the light emitting diode 33 on the power supply substrate 39, in the meantime, the heat generated from the light emitting diode 33 can be conducted to the power supply substrate 39 for achieving the purpose of increasing the heat conduction of the light emitting element 50.

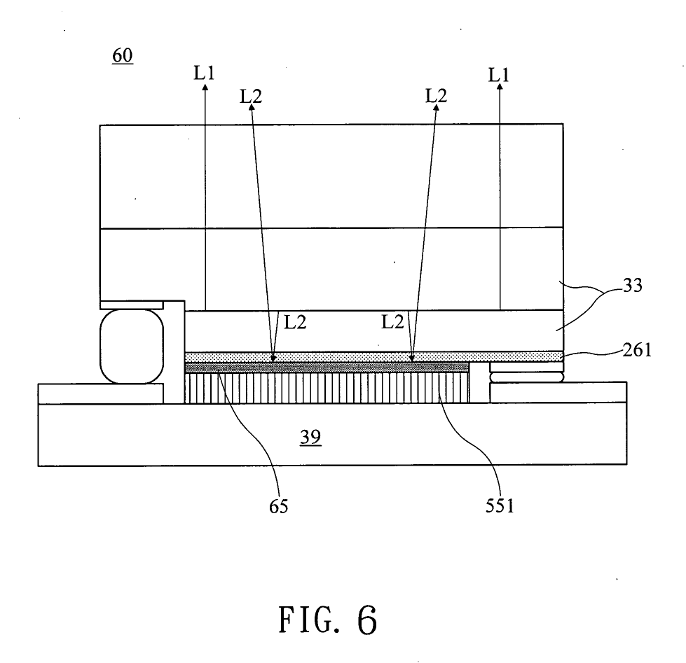

Referring to FIG. 6, is a vertical view of another preferred embodiment of the present invention. There is a difference from the FIG. 5. The light emitting element 60 comprises a light transparent electrical conductive layer 261 provided on the partial surface of the light emitting diode 33, and a reflection layer 65 provided on the partial surface of the light transparent electrical conductive layer 261. In other words, the light transparent isolation layer 261 will not be provided between the reflection layer 65 and the light transparent electrical conductive layer 261. The reflection layer 65 can be selectively as a photonic crystal structure with high reflection index or a multilayer thin-films reflection mirror with high reflection index, wherein the reflection layer 65 is an isolation material for preventing current conduction. Thus, the reflection layer 65 comprises the feathers including both of the reflection layer 25 and the light transparent isolation layer 263.

The reflection layer 65 is connected to the power supply substrate 39 through a heat conductive layer 551, such can advantage to conduct heat to the power supply substrate 39 through the heat conductive layer 551, and achieve the purpose of improving the brightness of the light emitting element 60, wherein the heat is generated from the light emitting element 60.

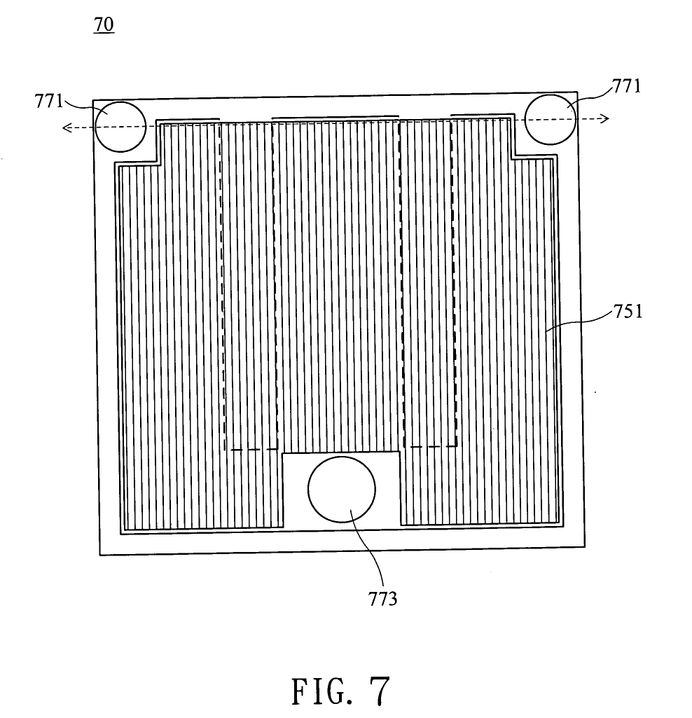

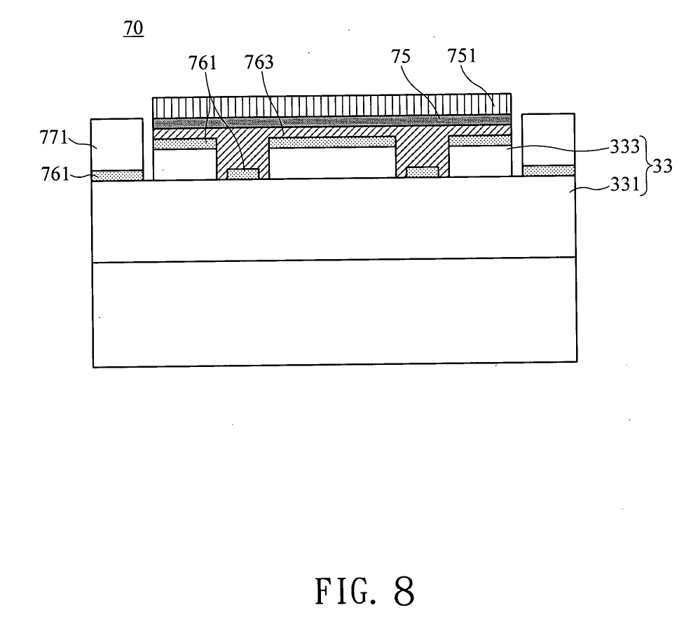

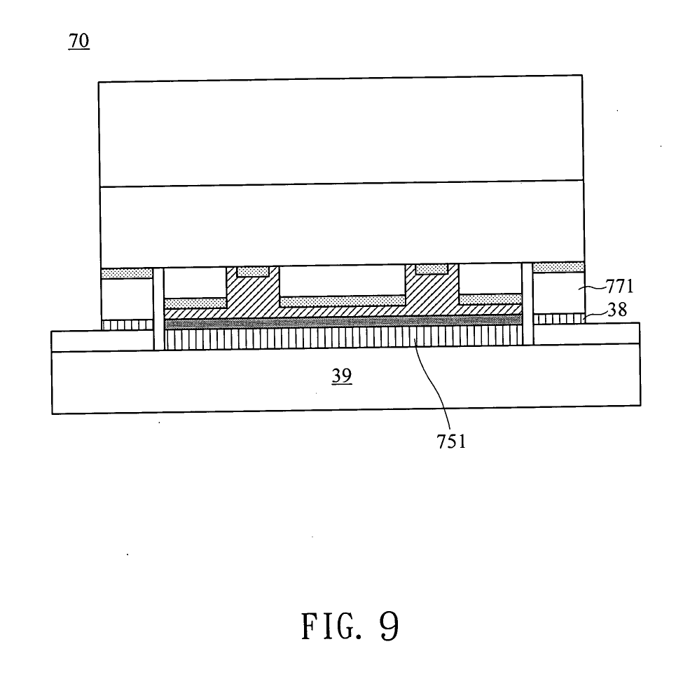

Referring to FIG. 7, FIG. 8, and FIG. 9, are respectively as a vertical view and structure cross sectional views of another preferred embodiment of the present invention. The light emitting element 70 comprises a light emitting diode 33, which comprises a first material layer 331 and a second material layer 333 stacked each other, and a light transparent electrical conductive layer 761 provided on the partial surface of the first material layer 331 and the second material layer 333. And, at least one first electrode 771 and at least one second electrode 773 are respectively provided on the partial surface of the light transparent electrical conductive layer 761 of the first material layer 331 and the second material layer 333, thus, the purpose of evenly power supplying for the first material layer 331 and the second material layer 333 can be achieved.

A light transparent isolation layer 763 is provided on the partial surface of the light transparent electrical conductive layer 761, and which can be extended to the partial surface of the first material layer 331. A reflection layer 75 and a heat conductive layer 751 are provided on the top of the light transparent isolation layer 763 in order, and further, the heat conductive layer 751 is with larger area for advantaging the heat conduction of the light emitting element 70.

Of course, the light transparent electrical conductive layer 763 of the first material layer 331 can be also selectively made by an opaque material with general electrical conduction, such that will not affect the purpose of maintaining the reflection index of the reflection layer 35, according to the provided of the light transparent isolation layer 763; and will not affect the purpose of improving the heat conductivity, according to the provided of the light transparent isolation layer 763 and the heat conductive layer 751.

Within another preferred embodiment of the present invention, the light emitting element 70 can be electrically connected to a power supply substrate 39 through a electrical conductive adhesive layer 38 for achieving the purpose of power supplying for the light emitting element 70, as shown on FIG. 9. The heat conductive layer 751 of the light emitting element 70 can be also contacted with the power supply substrate 39, which advantages to conduct out the heat generated when the light emitting element 70 is working.

In summary, it is appreciated that the present invention is related to a light emitting element, and more particularly to a reflection efficiency improved light emitting element, according to the light transparent electrical conductive layer and the reflection layer provided independently, the purpose of improving the brightness of the light emitting element being achieved.

The foregoing description is merely one embodiment of present invention and not considered as restrictive. All equivalent variations and modifications in process, method, feature, and spirit in accordance with the appended claims may be made without in any way from the scope of the invention.

I claim:

1. A reflection efficiency improved light emitting element, comprising:
a light emitting diode, comprising a first material layer and a second material layer stacked each other, at least one first electrode provided on the partial surface of said first material layer, at least one second material layer provided on the partial surface of said second material layer;
a light transparent electrical conductive layer provided on the surface of said second material layer, and electrically connected with said second electrode;
a light transparent isolation layer provided on said light transparent electrical conductive layer; and
a reflection layer provided on said light transparent isolation layer.

2. The light emitting element of claim 1, wherein said light transparent electrical conductive layer can be selectively as one of a metal oxide and a metal film material.

3. The light emitting element of claim 1, wherein said light transparent electrical conductive layer can be selectively as one of an ITO and an IZO.

4. The light emitting element of claim 1, wherein said light transparent electrical conductive layer can be extended to where between said second electrode and said second material.

5. The light emitting element of claim 1, wherein said reflection layer is a metal material.

6. The light emitting element of claim 1, wherein a plurality of ohm-contact points is provided between said light transparent electrical conductive layer and said second material layer.

7. The light emitting element of claim 1, wherein said light emitting diode further comprises a light transparent substrate provided on the other surface of said first material layer.

8. The light emitting element of claim 7, wherein the refractive index of said light transparent substrate is large than 1.7.

9. The light emitting element of claim 8, wherein said light emitting diode is provided on a power supply substrate by a flip chip way.

10. The light emitting element of claim 9, wherein said light emitting diode is connected with said power supply substrate through an electrical conductive adhesive layer.

11. The light emitting element of claim 9, wherein said electrical conductive adhesive layer can be selectively as one of a solder ball, an intermetallic material, and a gold-to-gold interconnect material.

12. The light emitting element of claim 1, wherein said reflection layer can be as a multilayer thin-films reflection mirror.

13. The light emitting element of claim 1, wherein at least one heat conductive layer is further provided on said reflection layer.

14. The light emitting element of claim 9, wherein at least one heat conductive layer is further provided on said reflection layer and contacted with said power supply substrate.

15. The light emitting element of claim 14, wherein an isolation layer is provided between said reflection layer and said heat conductive layer.

16. The light emitting element of claim 1, wherein said light transparent isolation layer can be extended to the partial surface of said first material layer.

17. The light emitting element of claim 1, wherein said light transparent electrical conductive layer is also provided on the partial surface of said first material layer.

18. The light emitting element of claim 17, wherein said light transparent isolation layer is provide on said light transparent electrical conductive layer.

19. A reflection efficiency improved light emitting element, comprising:
a light emitting diode, comprising a first material layer and a second material layer stacked each other, at least one first electrode provided on the partial surface of said first material layer, at least one second material layer provided on the partial surface of said second material layer;
a light transparent electrical conductive layer provided on the surface of said second material layer, and electrically connected with said second electrode;
a reflection layer provided on said light transparent electrical conductive layer, and being selectively as one of a multilayer thin-films reflection mirror and a photonic crystal structure; and
a heat conductive layer provided on the surface of said reflection layer.

20. The light emitting element of claim 19, wherein said light transparent electrical conductive layer can be extended to the partial surface of said first material layer.

21. The light emitting element of claim 19, wherein said reflection layer can be extended to the partial surface of said first material layer.
